(19) United States
(12) Patent Application Publication
(10) Pub. No.: US 2001/0052422 A1
(43) Pub. Date: Dec. 20, 2001

(54) Structure for supporting connecting member

(76) Inventors: Shigetaka Kobayashi, Shisou-gun (JP); Norio Ohki, Makabe-gun (JP); Shigeo Naoi, Makabe-gun (JP); Takashi Nagasawa, Makabe-gun (JP)

Correspondence Address: IBM CORPORATION, T.J. WATSON RESEARCH CENTER, P.O. BOX 218, YORKTOWN HEIGHTS, NY, 10598, US

(21) Appl. No.: 09/681,834

(22) Filed: Jun. 14, 2001

(30) Foreign Application Priority Data
Jun. 16, 2000 (JP) 2000-180697

(51) Int. Cl. H05K 1/11; H05K 1/14; H05K 1/00

(52) U.S. Cl. 174/250; 361/803

(57) ABSTRACT

A structure for supporting a connecting member having a base material for electrically and temporarily connecting a first substrate having a terminal and a second substrate having a connection pad with each other. A supporting point of a point for contacting between the second substrate and the connecting member and a supporting point of the first substrate are separated thermally.

### BACKGROUND OF INVENTION

The present invention relates to a structure for supporting a connecting member and more particularly to the structure used for supporting the connecting member for temporarily connecting substrates with each other.

Connection of substrates with each other has been heretofore carried out by using a connector and a cable, a jumper wire or the like.

However, with advancements in electronic devices the points for attaching the connector have become smaller, while costs spent for the connector have been reduced. A compact, thin and low-cost device has been requested. Even for jumper wires, the connection points have also been reduced.

Further, it is now necessary to make connections to a substrate having precise electrode patterns, such as a liquid crystal display apparatus or the like. Accordingly, a method has been developed to make an electrical connection between a substrate, having a matched conductor, with a precise electrode pattern by using an anisotropic conductive binding material.

Incidentally, with regard to the manufacture of such a liquid crystal substrate, defects easily occur because a large number of precise liquid crystal cells are to be formed in a matrix shape.

For example, even when the number of pixels is about 480×600, which is equivalent to that of a normal 13-inch television set, there are approximately 300 thousand pixels. Therefore, such defects may occur unless the defect rate is 1/300 thousand or lower. However, if one liquid crystal substrate is discarded because of one defect, almost all liquid crystal substrates can not be used, resulting in not only an increase of manufacturing costs but also a loss of a significance of existence of the liquid crystal substrate itself. In fact, although it depends on a size of one pixel, defects cannot be recognized by human eyes unless the defects occur around one point. Therefore, in the actual circumstances, the occurrence of defects is compromisingly accepted as long as there are no deteriorations in the quality of images.

However, it is impossible to determine how far the defects could be tolerated before the images are actually displayed. Thus, as an inspection practice, the liquid crystal substrate and a driving circuit thereof are temporarily connected together to inspect the quality of the images, and only the liquid crystal substrate passing the inspection can proceed to a next assembling step, where the liquid crystal substrate is connected to an actual driving circuit.

In the temporary connection made during the above inspection, the substrate and the liquid crystal substrate connected together may have different coefficients of thermal expansion, or the substrate and the liquid crystal substrate must be attached in a superposing manner. Accordingly, in the connection between the substrate and the liquid crystal substrate, a member having a conductor for connecting, formed on a flexible base material has been frequently used. Thereby allowing base materials having different coefficients of thermal expansion to be connected together.

With regard to such a temporary connection, the inspection is to be carried out by making alignment while heating a connecting member and maintaining a connection while extending the connecting member has been proposed. However, when an adjustment is made by heating the connecting member, so as to be extended, it is also difficult to make alignment in a state where a portion of the driving circuit, of the connecting member connected to the substrate, in which the driving circuit is loaded thereon is not supported. Thus, for temporarily fixing the driving circuit with an adhesive or the like, a supporting structure is made to be in contact with the backside of the connecting member.

However, when alignment is made while heating the connecting member, and connection is maintained while the connecting member is extended, and when a heating head housing a heater or the like is brought into contact from the backside of the structure for supporting the connecting member, then only the contact portion is expanded or contracted and becomes a distorted shape. Consequently, the substrate cannot be expanded as desired, it takes too long before heat reaches the entire structure for supporting the connecting member, and the effect of heating does not appear immediately. Even in the middle of the time when a test was being conducted, a solid connection could not be maintained sometimes.

### SUMMARY OF INVENTION

An object of the present invention is to provide a structure for supporting a connecting member, which is superior in heat conductivity and workability.

A structure for supporting a connecting member of the present invention comprises a base material for electrically and temporarily connecting a first substrate having a terminal and a second substrate having a connection pad with each other, wherein a supporting point of a point for contacting between the second substrate and the connecting member and a supporting point of the first substrate are separated thermally.

### BRIEF DESCRIPTION OF DRAWINGS

For a more complete understanding of the present invention and the advantages thereof, reference is now made to the following description taken in conjunction with the accompanying drawings.

FIG. 1(a) is a top schematic view showing one embodiment of the present invention.

FIG. 1(b) is a side view of the embodiment according to the present invention.

FIG. 2(a) is a top view, for the purpose of a description, showing a state where a liquid crystal display substrate, one horizontal driving circuit substrate and one vertical driving circuit substrate, which are used in the embodiment of the present invention, are connected.

FIG. 2(b) is a side view showing the state of connection.

FIG. 3 is a schematic side view showing a structure of bonding device used in the embodiment of the present invention.

FIG. 4 is a side view showing the state of connection according to another embodiment of the present invention.

FIG. 5(a) is a top schematic view showing a conventional example.

FIG. 5(b) is a side view of FIG. 5(a).

### DETAILED DESCRIPTION

The structure for supporting a connecting member, a supporting point of the point for making contact between the second substrate and the connecting member and the supporting point of a first substrate should be preferably connected by a thin base material for the purpose of creating a thermal separation for the supporting point for making contact between the second substrate, the connecting member and the supporting point of the first substrate.

In addition, the supporting point of the point for contacting between the second substrate and the connecting member and the supporting point of the first substrate should preferably be made from the identical base materials for economical reasons.

Furthermore, a material having a coefficient of thermal expansion substantially equal to that of the connecting member is preferable for use, as stresses applied on both can be reduced while a connection is maintained.

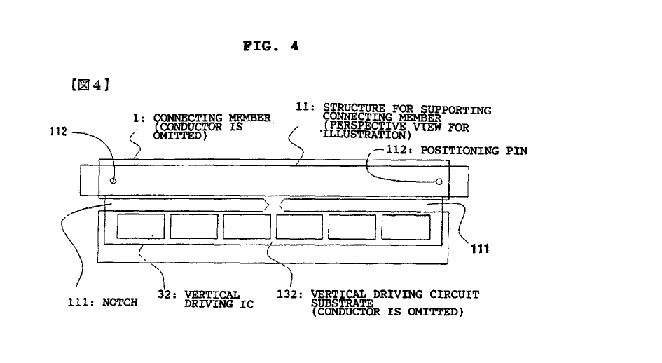

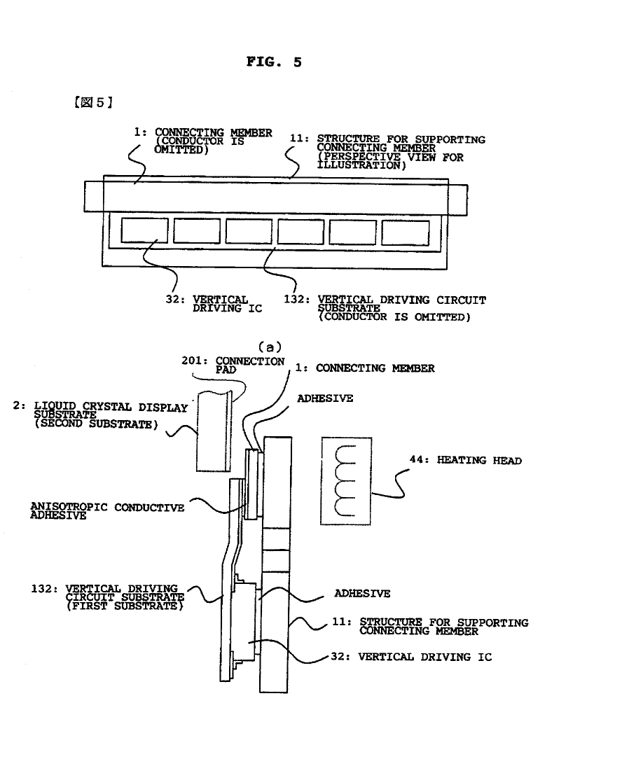

As shown in FIG. 4, positioning holes in each of the first substrate 132 and the connecting member 1, and a positioning pin 112 corresponding to the positioning hole in the structure for supporting the connecting member 11 should be preferably provided. In this way, alignment work can be facilitated.

According to the present invention, for the second substrate, a glass substrate having a liquid crystal cell formed thereon or other printed wiring boards can be used.

For the first substrate, other than the foregoing, a semiconductor package such as a flip chip or a flat package, or a substrate having a plurality of such packages loaded thereon can be also used.

In the connecting member 1 of the present invention, if a pitch between conductors is less than 0.02 mm, a method of etching cannot be used for mass production of the usual wiring boards, which loses an economical advantage. Moreover, if a pitch exceeds 2 mm, connection can be efficiently made even without heating and extending the connecting member. Thus, a pitch should be preferably set in the range of 0.02 to 2 mm and, more preferably, in the range of 0.04 to 0.1 mm.

The connecting member 1 of the present invention includes a conductor and an insulating substrate 11 for supporting the conductor. Specifically, with regard to the conductor, metallic foil especially copper foil, aluminum foil or the like used for a normal printed wiring board is suitable for forming the conductor. For a base material of the insulating substrate, a flexible insulating material should be preferably used. For example, a base material of glass cloth impregnated with epoxy resin, a polyester film, a polyimide film or the like having a thickness of 0.2 mm or less is available. Among of all, the base material of glass cloth impregnated with epoxy resin and the polyester film are preferable as they are superior in portability and processability.

In addition, for adjusting alignment of the terminals of base materials having a difference in coefficients of thermal expansion while heating, a base material for the connecting member should be more preferably a material having a uniform coefficient of thermal expansion. Other than the above, a metal plate covered to be insulated can be also used.

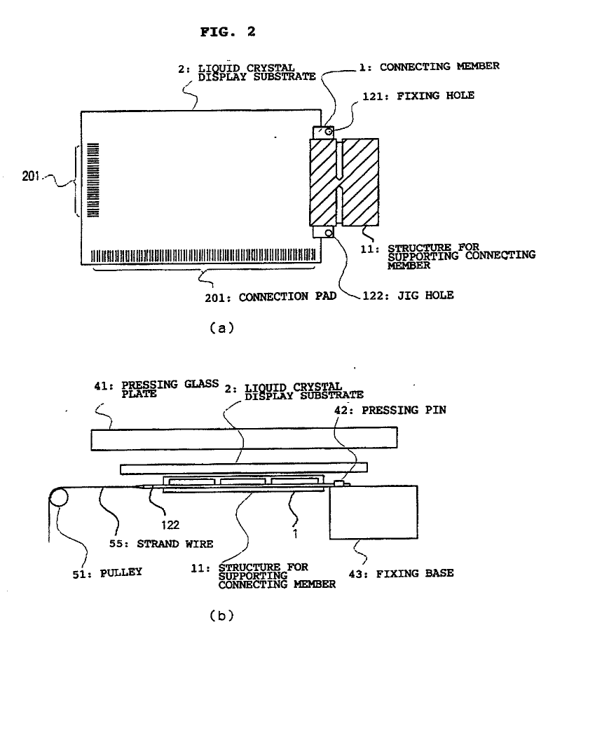

As shown in FIG. 2(a), a second substrate was fabricated as follows. An ITO film was formed on a glass substrate having a thickness of 0.7 mm. A thin film transistor (TFT) is used as a liquid crystal cell. A connection pad of a transparent electrode for connecting to the driving circuit of a liquid crystal, connection pads, each having a width of 0.035 mm, connected to a horizontal driving line, are arrayed on the left and right sides of the glass substrate at a constant pitch of 0.06 mm; a pitch of a point equivalent to a part between IC packages is set larger, that is, at a pitch of 4.8 mm; connection pads, each having a width of 0.04 mm, connected to a vertical driving line, are arrayed on the upper and lower sides of the glass substrate at a constant pitch of 0.08 mm; and a pitch of a point equivalent to a part between IC packages is set larger, that is, at a pitch of 4.8 mm.

A first substrate was fabricated as follows. A circuit is provided by performing etching of copper foil on one surface of an MCL-E-679 (product name, manufactured by Hitachi Chemical Co., Ltd.) having a thickness of 0.1 mm, which is a copper clad laminate using copper foil having a thickness of 18 microns. All of the copper foil portions on the other surface are removed by etching, and an AC-7244 (product name, manufactured by Hitachi Chemical Co., Ltd.) which is an anisotropic conductive adhesive film having a width of 1.2 mm is laminated on the circuit. The backside of the substrate, the connection point to a horizontal driving IC 31 or a vertical driving IC 32 is pierced through for creating an alignment. Heating and pressurization are applied under the condition of 2 MPa at a temperature of 170 degrees, and adhesion is then carried out. Then three horizontal driving ICs 31 (first substrate) are bonded on one connecting member 1 to fabricate one horizontal driving circuit 310. Also, a circuit is provided by performing etching of copper foil on one surface of an MCL-E-679 (product name, manufactured by Hitachi Chemical Co., Ltd.) having a thickness of 0.1 mm, which is a copper clad laminate using copper foil having a thickness of 18 microns. All of the copper foil portions on the other surface are removed by etching, and AC-7244 (product name, manufactured by Hitachi Chemical Co., Ltd.), which is an anisotropic conductive adhesive film having a width of 1.2 mm, is laminated on the circuit. Another side of the substrate, the connection point to the horizontal driving IC 31 or the vertical driving IC 32 is pierced through for creating an alignment. Heating and pressurization are applied under the condition of 2 MPa at a temperature of 170 degrees, and adhesion is then carried out. Six vertical driving ICs 32 (first substrate) are bonded on one connecting member to fabricate one vertical driving circuit 320.

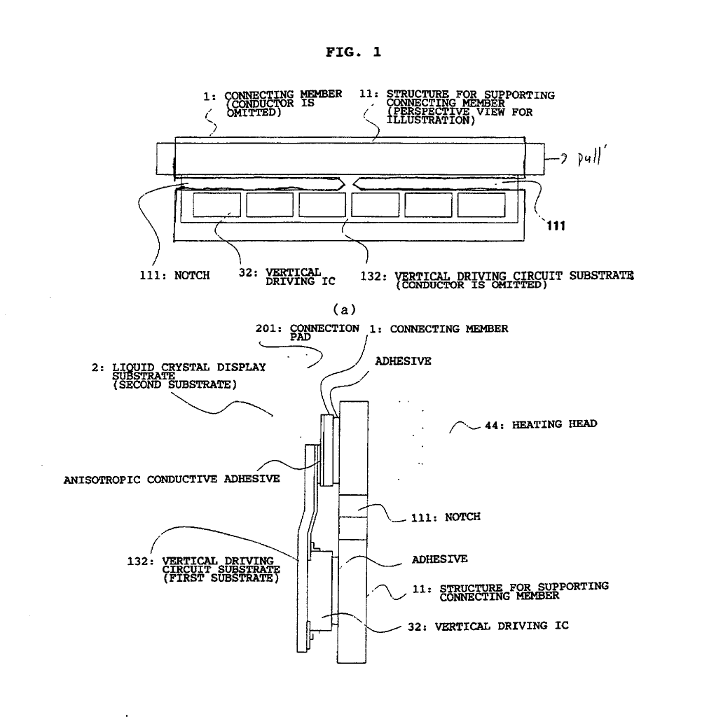

With regard to the connecting member 1, as in the case of the first substrate FIG. 1, a circuit is provided by performing etching of copper foil on one surface of an MCL-E-679 (product name, manufactured by Hitachi Chemical Co., Ltd.) having a thickness of 0.1 mm, which is a copper clad laminate using copper foil of a thickness of 18 microns, all copper foil portions on the other surface are removed. The member connected to a horizontal driving circuit substrate 131 is provided with 256 pins of terminals 33 at a pitch of 0.06 mm in one side. The member connected to a vertical driving circuit substrate 132 is provided with 384 pins of terminals 33 at a pitch of 0.08 mm.

A conductor pattern formed in the horizontal driving circuit substrate 131 had a width of 0.03 mm, and a trapezoidal shape in section. A width of the surface not in contact with the insulating base material was 0.01 mm. A conductor pattern formed in the vertical driving circuit substrate 132 had a width of 0.04 mm, and a trapezoidal shape in section. A width of the surface not in contact with the insulating base material was 0.012 mm.

In the connecting member 1, a fixing hole 121, FIG. 2(a), and a jig hole 122, through which a strand wire 55 for pulling is passed, were bored in both ends of the conductor pattern.

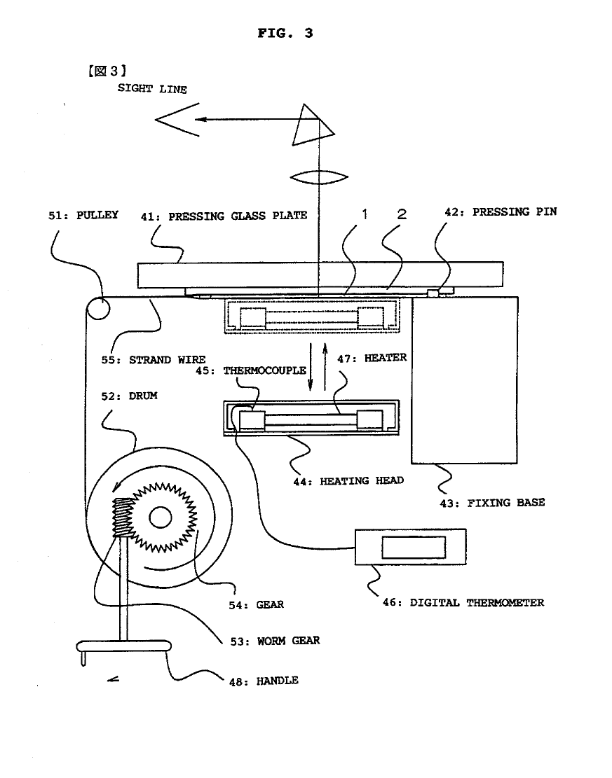

The connection of the liquid crystal display substrate 2 with the horizontal driving circuit substrate 131 and vertical driving circuit substrate 132 was carried out as follows. That is, as shown in FIG. 1(b), the structure for supporting the connecting member 11 was fabricated by performing etching to remove all copper foil on both surfaces of a glass epoxy copper clad laminate MCL-E-679 (product name, manufactured by Hitachi Chemical Co., Ltd.) having a thickness of 1 mm to 4 mm. The horizontal driving IC 31 of the horizontal driving circuit substrate 131 was adhered and fixed to the vertical driving IC 32 of the vertical driving circuit substrate 132 by adhesive. Then, a pressing pin 42 FIG. 2(b) was pushed into the fixing hole 121 of the connecting member 1 and a hole provided in a fixing base 43 to fix one end thereof. The strand wire 55 is inserted into the jig hole 122 in the other end of the connecting member 1 to be hanged over a pulley 51. To protect the liquid crystal display substrate 2 from above and to bring the conductor pattern of the connecting member 1 and the terminal pattern of the liquid crystal display substrate 2 into contact with each other by sandwiching with a later-described heating head 44 FIG. 1(b) to apply pressurization, a pressing glass plate 41 was placed. Furthermore, as shown in FIG. 3, the strand wire 55 is wound around a drum 52. A worm gear 53 engaged with a gear 54 fixed to the same shaft to which the drum 52 was fixed so as to be rotated by a handle 48. Alignment was made while piercing through the terminal pattern (transparent electrode) of the liquid crystal display substrate 2 and the conductor pattern of the connecting member 1, from the backside of the liquid crystal display substrate 2. The temperature of the heating head 44, in which a heater 47 was provided, was set at 20 degrees. When the temperature measured by a digital thermometer 46 connected to a thermocouple 45 provided in the heating head 44 was stabilized, the heating head 44 was moved into contact with the backside of the connecting member 1. The strand wire 55 attached to the connecting member 1 was pulled by rotating the handle 48. When a pitch of the conductor pattern of the connecting member 1 was not aligned with the pitch of the terminal pattern of the liquid crystal display substrate 2 even by rotating the handle (pulling of 10 micrometers), the temperature was further increased by 10 degrees for adjustment. Then, when alignment was achieved, a switch of the driving circuit was turned on to conduct an operation test of the liquid crystal display substrate 2.

At this time, the pitch of the conductor pattern of the connecting member 1 was designed to correspond to the pitch of the terminal pattern of the liquid crystal display substrate 2, based on a thermal expansion coefficient of the connecting member 1, when the heating head 44 was at 30 degrees. The operations of heating/pulling were started at a temperature lower by 10 degrees.

The operation test was actually conducted for two vertical driving circuit substrates 132 and two horizontal driving circuit substrates 131 simultaneously.

As a result of the foregoing connection, the inventors found that the adjustment of alignment could be executed at the heating temperature in the range of 30 to 70 degrees, and moreover, during the test, no failures occurred in the connection between the connecting member 1, the liquid crystal display substrate 2, the horizontal driving IC 31 or the vertical driving IC 32.

As described above, according to the present invention a structure for supporting a connecting member having superior thermal stability and workability, which is capable of adjusting misalignment caused by differences in thermal expansion coefficient in heating and extending the connecting member can be provided.

Although the preferred embodiments of the present invention have been described in detail, it should be understood that various changes, substitutions and alternations can be made therein without departing from spirit and scope of the inventions as defined by the appended claims.

1. A structure for supporting a connecting member, comprising:
a base material for electrically and temporarily connecting a first substrate having a terminal and a second substrate having a connection pad with each other, wherein a supporting point of a point for contacting between the second substrate and the connecting member and a supporting point of the first substrate are separated thermally.

2. The structure for supporting the connecting member according to claim 1, wherein the supporting point of the point for contacting between the second substrate and the connecting member and the supporting point of the first substrate are connected by a thin base material.

3. The structure for supporting the connecting member according to claim 1, wherein the supporting point of the point for contacting between the second substrate and the connecting member and the supporting point of the first substrate are made of identical base materials.

4. The structure for supporting the connecting member according to claim 1, wherein a material having a coefficient of thermal expansion substantially equal to that of the connecting member is used.

5. The structure for supporting the connecting member according to claim 1, wherein positioning holes are provided in each of the first substrate and the connecting member, and a positioning pin is provided corresponding to the positioning hole in the structure for supporting the connecting member.

6. The structure for supporting the connecting member according to claim 2, wherein the supporting point of the point for contacting between the second substrate and the connecting member and the supporting point of the first substrate are made of identical base materials.

7. The structure for supporting the connecting member according to claim 3, wherein a material having a coefficient of thermal expansion substantially equal to that of the connecting member is used.

8. The structure for supporting the connecting member according to claim 4, wherein positioning holes are provided in each of the first substrate and the connecting member, and a positioning pin is provided corresponding to the positioning hole in the structure for supporting the connecting member.

9. The structure for supporting the connecting member according to claim 6, wherein a material having a coefficient of thermal expansion substantially equal to that of the connecting member is used.

10. The structure for supporting the connecting member according to claim 7, wherein positioning holes are provided in each of the first substrate and the connecting member, and a positioning pin is provided corresponding to the positioning hole in the structure for supporting the connecting member.

11. The structure for supporting the connecting member according to claim 9, wherein positioning holes are provided in each of the first substrate and the connecting member, and a positioning pin is provided corresponding to the positioning hole in the structure for supporting the connecting member.
